(19) United States
(12) Patent Application Publication
(10) Pub. No.: US 2013/0244370 A1
(43) Pub. Date: Sep. 19, 2013

(54) METHOD FOR PRODUCING PHOTOELECTRIC CONVERSION DEVICE

(71) Applicant: FUJIFILM CORPORATION, Tokyo (JP)

(72) Inventor: Yoshio TADAKUMA, Kanagawa-ken (JP)

(73) Assignee: FUJIFILM CORPORATION, Tokyo (JP)

(21) Appl. No.: 13/887,025

(22) Filed: May 3, 2013

Related U.S. Application Data
(63) Continuation of application No. PCT/JP2011/006159, filed on Nov. 2, 2011.

(30) Foreign Application Priority Data
Nov. 9, 2010 (JP) 2010-250395

(51) Int. Cl. H01L 31/18

(52) U.S. Cl. CPC H01L 31/18
USPC 438/95

(57) ABSTRACT

In a method for producing a photoelectric conversion device including a light absorption layer made of a CIGS-based compound semiconductor, a vacancy formation process for forming Cu vacancies in a surface layer of the light absorption layer in a layered member that is composed of a lower electrode and the light absorption layer deposited on a substrate is performed, and after then, a pn junction is formed in the surface layer of the light absorption layer.

### BACKGROUND OF THE INVENTION

1. Field of the Invention

The present invention relates to a method for producing photoelectric conversion devices used in solar cells, CCD sensors, or the like.

2. Description of the Related Art

A photoelectric conversion device including a photoelectric conversion layer (light absorption layer) and an electrode electrically connected to the photoelectric conversion layer is used for various purposes, such as solar cells. Conventionally, the main trend of solar cells was Si-based solar cells using bulk monocrystalline Si or polycrystalline Si, or a thin film of amorphous Si. However, research and development of compound semiconductor-based solar cells that do not rely on Si are being carried out. As the compound semiconductor-based solar cells, a bulk system, such as GaAs system, and a thin film system, such as CIGS system composed of a group Ib element, a group Mb element, and a group VIb element, are known. The CIGS-based semiconductor is a compound semiconductor represented by the general formula of Cu_{1-z}In₁₋ₓGaₓSe_{2-y}S_{y} (in the formula, 0≦x≦1, 0≦y≦2, and 0≦z≦1). The formula represents a CIS semiconductor when x=0, and a CIGS semiconductor when x>0.

It is considered that introduction of divalent cations of Cd, Zn or the like into a CIGS layer is necessary to provide a photoelectric conversion function in a CIGS-based photoelectric conversion device. More specifically, it is considered that divalent cations of Zn or Cd diffuse in a surface layer of the CIGS layer, and act as donors, and that they change a region of the CIGS layer in which they have diffused to an n-type semiconductor, and that a pn junction is formed between the n-typed CIGS in the surface layer portion and originally p-typed CIGS that is present in the inside, and a photoelectric conversion function is generated.

In a general method for forming a pn junction, a buffer layer composed of ZnS, CdS or the like is formed on a CIGS layer, and Zn or Cd, which is a part of the buffer layer, is diffused by substituting Cu in a surface layer of CIGS. As a result, a pn junction is formed at an interface between the two layers (Japanese Patent No. 4320529 (Patent Document 1), and the like). It has been reported that especially when a buffer layer made of ZnS, CdS or the like is deposited by using a chemical bath deposition method (CBD), Zn or Cd, which is a part of the buffer layer, substitutes Cu in a surface layer of a CIGS layer during deposition of the buffer layer, and Zn ions or Cd ions diffuse in the CIGS layer in an excellent manner, and a high photoelectric conversion efficiency is achievable.

Meanwhile, Japanese Patent No. 3337494 (Patent Document 2) discloses a method for diffusing a II group dopant in a CIGS layer by carrying out a heating process after causing a II group element to deposit by vapor deposition together with CIGS without forming a buffer layer, or after forming a CIGS layer and further forming a II group element coating on the surface of the CIGS layer.

Meanwhile, when a growth of a CIGS layer is accelerated to increase a production speed, the surface of the CIGS layer becomes less even, and the unevenness of the surface makes coverage by a buffer layer formed on the uneven surface insufficient. Consequently, there is a problem that a leak electric current is generated. Therefore, a pamphlet of International Patent Publication No. 2005/069386 (Patent Document 3) discloses a method for increasing resistance by diffusing n-type impurities in a part of a CIGS layer. The n-type impurities are diffused by depositing the n-type impurities on a CIGS layer exposed to a pinhole portion of the buffer layer (or a window layer), which covers insufficiently, and by heating the n-type impurities.

In the method of Patent Document 3, it is considered that a main pn junction is formed at an interface between the CIGS layer and the buffer layer (or the window layer). It is not clear whether an n-type dopant diffused from the pinhole portion acts to form a pn junction.

### SUMMARY OF THE INVENTION

Both of the methods disclosed in Patent Documents 2 and 3 need to carry out a heating process to diffuse n-type dopants. Therefore, the sizes of the apparatuses are large, and there is a problem that a cost of production becomes higher.

Further, in the method disclosed in Patent Document 3, the size and the density of pinholes of the buffer layer (or the window layer) formed on the surface of the CIGS layer are not uniform. Therefore, a pn junction may be extremely uneven, and there is a risk that electricity generation efficiencies vary.

Further, in general buffer layer formation, diffusion of n-type dopants is not sufficiently even, because they diffuse by entering Cu vacancies that are spontaneously generated on the surface of CIGS, or by substituting existing Cu. Further, it is difficult to sufficiently increase the density of diffused n-type dopants while maintaining an appropriate thickness of the buffer.

In view of the foregoing circumstances, it is an object of the present invention to provide a method for producing a photoelectric conversion device that can easily and evenly diffuse n-type dopant in a light absorption layer with a sufficient density of diffusion, and which can achieve a high photoelectric conversion efficiency.

A method for producing a photoelectric conversion device of the present invention is a method for producing a photoelectric conversion device including a light absorption layer made of a CIGS-based compound semiconductor, wherein a vacancy formation process for forming Cu vacancies in a surface layer of the light absorption layer in a layered member that is composed of a lower electrode and the light absorption layer deposited on a substrate is performed, and after then, a pn junction is formed in the surface layer of the light absorption layer.

It is desirable that the layered member is immersed in a reaction solution containing multivalent cations, and the pH of which is in the range of 0 to 7, and that the pn junction is formed by arranging a counter electrode for applying an electric field in such a manner to face the light absorption layer, and by diffusing the multivalent cations from the surface layer of the light absorption layer to the inside of the light absorption layer by inducing a difference in electric potential between the counter electrode and the lower electrode in such a manner that the electric potential of the lower electrode is lower than that of the counter electrode.

In other words, it is desirable that the pn junction is formed by diffusing the multivalent cations (n-type dopant) in the light absorption layer by electrodeposition.

Instead, the pn junction may be formed without diffusing the multivalent cations in the light absorption layer by the electrodeposition. After the vacancy formation process, a buffer layer may be formed on a surface of the light absorption layer, and the pn junction may be formed in the process of forming the buffer layer.

As the vacancy formation process, it is desirable that at least a surface layer of the layered body is immersed in an aqueous solution containing at least one kind of amines.

Further, as the at least one kind of amines, at least one selected from a group consisting of ethylenediamine, diethylenetriamine, triethylenetetramine, tetraethylenepentamine, and pentaethylenehexamine may be desirably used.

Especially, triethylenetetramine or tetraethylenepentamine is desirable.

It is desirable that the multivalent cations are ions of a IIa group element or IIb group element.

Especially, Zn²⁺ or Cd²⁺ is desirable.

It is desirable to use, as the substrate, an anodized substrate selected from a group consisting of an anodized substrate in which an anodized film containing Al₂O₃ as a main component is formed at least on one surface side of an Al base material containing Al as a main component, an anodized substrate in which an anodized film containing Al₂O₃ as a main component is formed at least on one surface side of a composite base material composed of an Fe material containing Fe as a main component and an Al material containing Al as a main component at least on one surface side of the Fe material, and an anodized substrate in which an anodized film containing Al₂O₃ as a main component is formed at least on one surface side of a base material in which an Al coating containing Al as a main component is formed at least on one surface side of a Fe material containing Fe as a main component.

According to the method for producing a photoelectric conversion device of the present invention, Cu vacancies are formed in a surface layer of a light absorption before a pn junction is formed. Therefore, it is possible to easily and evenly diffuse multivalent cations in the light absorption layer. Further, it is possible to sufficiently increase the density of diffusion in a short time period. Therefore, it is possible to shorten a production process, and to obtain a uniform photoelectric conversion device having a high photoelectric conversion rate.

Especially, when a method for diffusing multivalent cations in a light absorption layer by electrodeposition by immersing at least the light absorption layer of a layered member composed of a lower electrode and the light absorption layer deposited on a substrate is used to form a pn junction, it is possible to overwhelmingly reduce time required for forming a pn junction, compared with a case of forming a pn junction by depositing a buffer layer on a light absorption layer by using a general chemical bath deposition method (CBD method). In the CBD method, a high-concentration ammonia solution is used as a reaction solution. Therefore, a substrate used in the CBD method is limited. However, when deposition of a buffer layer by the CBD method is not performed, the substrate may be selected from a wide range of substrates.

In actual application, these feature are extremely desirable because it is possible to suppress a production cost.

### BRIEF DESCRIPTION OF THE DRAWINGS

FIG. 1 is a schematic cross section illustrating an example of a photoelectric conversion device produced by using a production method of the present invention;

FIG. 2 is a schematic cross section illustrating a layered member;

FIG. 3A is a schematic diagram illustrating an ideal arrangement of CIS in a surface layer of a light absorption layer;

FIG. 3B is a schematic diagram illustrating a real arrangement of CIS in a surface layer of a light absorption layer;

FIG. 4 is a schematic diagram illustrating a step of forming Cu vacancies in a light absorption layer;

FIG. 5A is a schematic diagram illustrating a step of forming Cu vacancies in a surface layer of the light absorption layer (No. 1);

FIG. 5B is a schematic diagram illustrating a step of forming Cu vacancies in the surface layer of the light absorption layer (No. 2);

FIG. 6 is a schematic diagram illustrating a step of forming a pn junction by electrodeposition;

FIG. 7A is a schematic diagram illustrating a step of forming a pn junction in a surface layer of a light absorption layer (No. 1);

FIG. 7B is a schematic diagram illustrating a step of forming the pn junction in the surface layer of the light absorption layer (No. 2);

FIG. 7C is a schematic diagram illustrating a step of forming the pn junction in the surface layer of the light absorption layer (No. 3);

FIG. 8 is a schematic cross section illustrating a photoelectric conversion device of a design modification example;

FIG. 9A is a schematic cross section illustrating the structure of an anodized substrate; and

FIG. 9B is a schematic cross section illustrating the structure of an anodized substrate.

### DESCRIPTION OF THE PREFERRED EMBODIMENTS

Hereinafter, the present invention will be described in detail.

First, a general structure of a photoelectric conversion device produced by using a method for producing the photoelectric conversion device of the present invention will be described with reference to drawings.

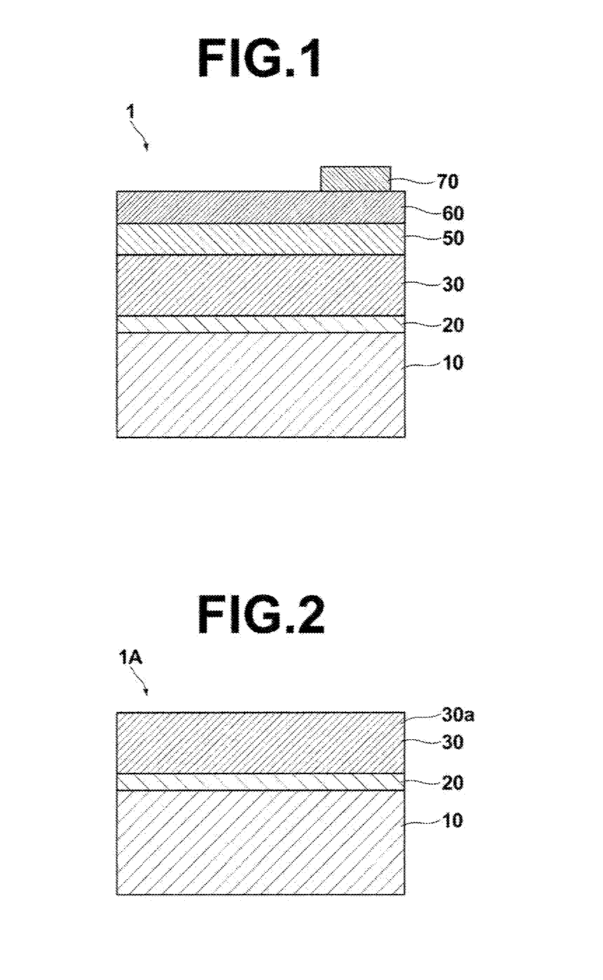

FIG. 1 is a schematic cross section of a photoelectric conversion device. In FIG. 1, composition elements are appropriately illustrated in different scale from actual one so as to be easily recognizable.

A photoelectric conversion device 1 is a device in which a lower electrode (back side electrode) 20, a light absorption layer 30 made of a CIGS-based composition semiconductor, a window layer 50, a transparent conductive layer (transparent electrode) 60, and an extraction electrode 70 are placed one on another in this order on a substrate 10.

Here, the CIGS-based compound semiconductor is a compound semiconductor represented by the general formula of Cu_{1-z}In₁₋ₓGaₓSe_{2-y}S_{y} (in the formula, 0≦x≦1, 0≦y≦2, and 0≦z≦1).

A method for producing a photoelectric conversion device of the present invention is a method in which a vacancy formation process for forming Cu vacancies 31 in a surface layer 30a of a light absorption layer 30 in a layered member 1A that is composed of a lower electrode 20 and the light absorption layer 30 deposited on a substrate 10 is performed, and after then, a pn junction is formed in the surface layer 30a of the light absorption layer 30.

The production method of the present embodiment will be described.

First, as illustrated in FIG. 2, the lower electrode 20 and the light absorption layer 30 made of a CIGS-based compound semiconductor are deposited in this order on the substrate 10, and this member is used as a layered member 1A.

Various known methods may be used to form the lower electrode 20 and the light absorption layer 30.

Next, Cu vacancies are formed in the surface layer 30a of the light absorption layer 30 in the layered member 1A. A process of forming such Cu vacancies will be described.

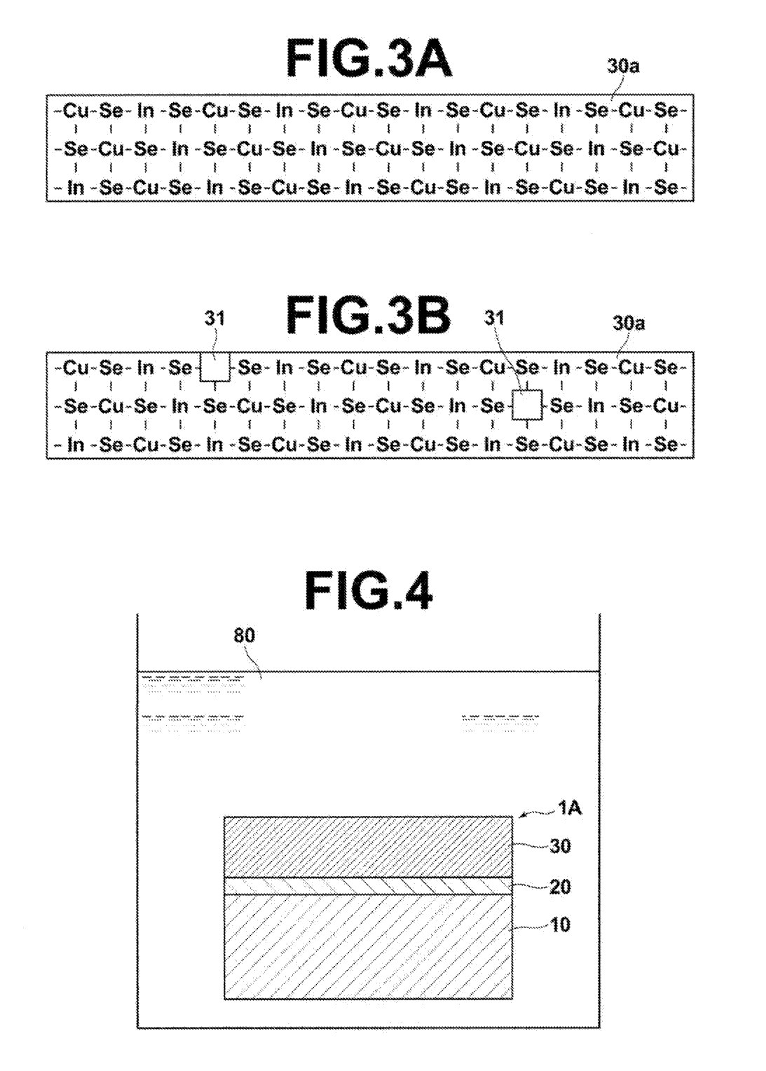

FIG. 3A is a schematic diagram illustrating a crystal of a CIGS compound semiconductor. FIG. 3A is a diagram for explaining movement of atoms or vacancies in an easily understandable manner, and the crystalline structure does not necessarily correspond to an actual crystalline structure. Here, the light absorption layer 30 is assumed to be made of CuInSe₂, and Cu and In are arranged alternately with Se therebetween. However, as illustrated in FIG. 3B, an actual light absorption layer has vacancies 31 in which Cu is not present at positions where Cu should be located in an ideal crystal. The vacancies present at positions where Cu should be located are referred to as Cu vacancies 31. Generally, a buffer layer of CdS, ZnS or the like is formed on the light absorption layer including such spontaneously-formed vacancies. When the buffer layer is formed, Cd, Zn or the like enters the Cu vacancies, or substitutes existing Cu. Consequently, cations (n-type dopant) diffuse in the light absorption layer.

In the production method of the present invention, a vacancy formation process is performed to more actively form the Cu vacancies 31. Specifically, as illustrated in FIG. 4, the layered member 1A in which the lower electrode 20 and the light absorption layer 30 are formed on the substrate 10 is immersed in an aqueous solution 80 containing at least one kind of amines. When the layered member 1A is immersed in the aqueous solution 80, the at least one kind of amines in the aqueous solution is adsorbed on Cu in a surface layer of the CIGS layer, and draws Cu into the aqueous solution. As a result, Cu vacancies are formed in the surface layer of the CIGS layer.

Here, the layered member 1A itself is immersed in the aqueous solution, but it is sufficient if a surface of the light absorption layer 30 in the layered member 1A touches the aqueous solution 80.

As amines, for example, ethylenediamine, diethylenetriamine, triethylenetetramine, tetraethylenepentamine, and pentaethylenehexamine may be used. Especially, triethylenetetramine or tetraethylenepentamine is desirable.

It is desirable that the concentration of amines in the aqueous solution is in the range of about 1 weight % to 10 weight %. If the concentration of amines is too low, formation of vacancies is not sufficient. If the concentration is too high, it is not desirable because vacancies are excessively formed.

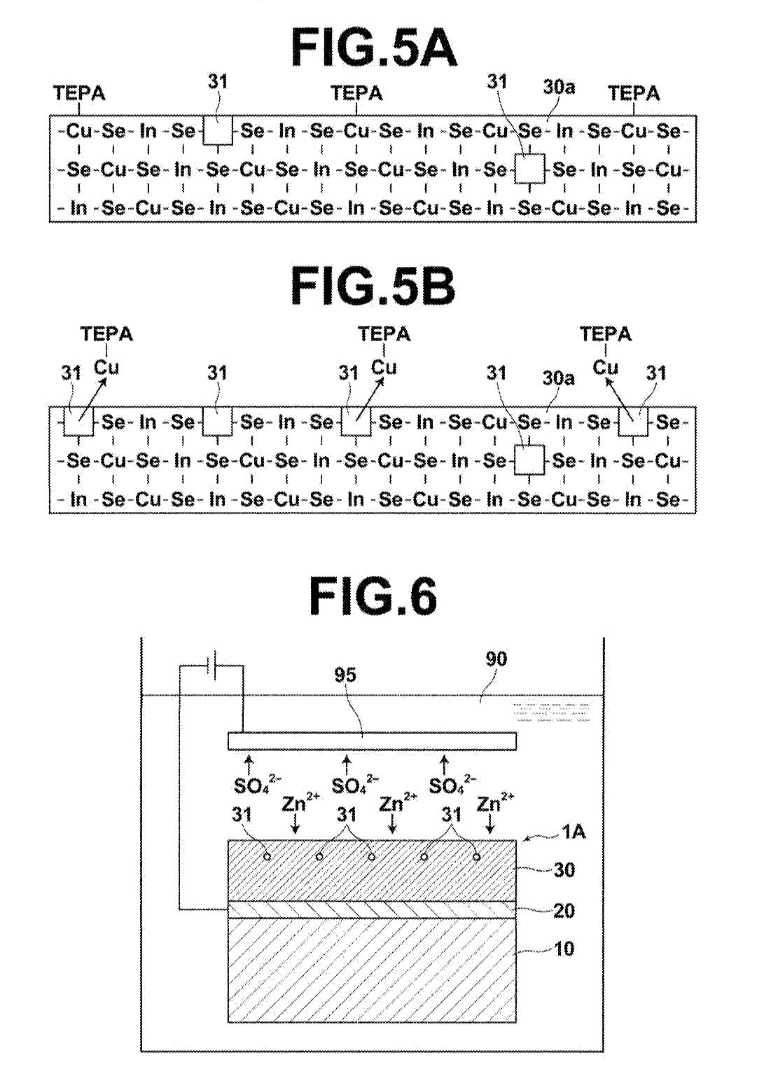

FIGS. 5A and 5B are schematic diagrams illustrating the state of the surface layer during a vacancy formation process.

As illustrated in FIG. 5A, when the surface layer 30a of the light absorption layer 30 touches the aqueous solution 80 containing at least one kind of amines, the at least one kind of amines (in FIG. 5, tetraethylenepentamine TEPA) is adsorbed on Cu in the surface layer 30a.

Then, as illustrated in FIG. 5B, TEPA draws Cu in the surface layer 30a into the aqueous solution. As a result, many Cu vacancies 31 are formed in the surface layer 30a.

When Cu vacancies 31 are actively formed in this manner, it is possible to efficiently form even pn junctions when pn junctions are formed later.

As illustrated in FIG. 6, a layered body 1A in which Cu vacancies 31 are formed in the light absorption layer 30 is immersed in a reaction solution 90 containing multivalent cations, and the pH of which is in the range of 0 to 7. A counter electrode 95 for applying an electric field is arranged in such a manner to face the light absorption layer 30, and a difference in electric potential is induced between the counter electrode 95 and the lower electrode 20 in such a manner that the electric potential of the lower electrode 20 is lower than that of the counter electrode 95 to form a pn junction. In the present embodiment, an electrolyte solution of zinc sulfate is used as the reaction solution 90. Specifically, multivalent cations are Zn²⁺, and when voltage is applied between the counter electrode 95 and the lower electrode 20, Zn²⁺ is attracted to the surface side of the light absorption layer 30, and SO₄²⁻ is attracted to the counter electrode 95 side.

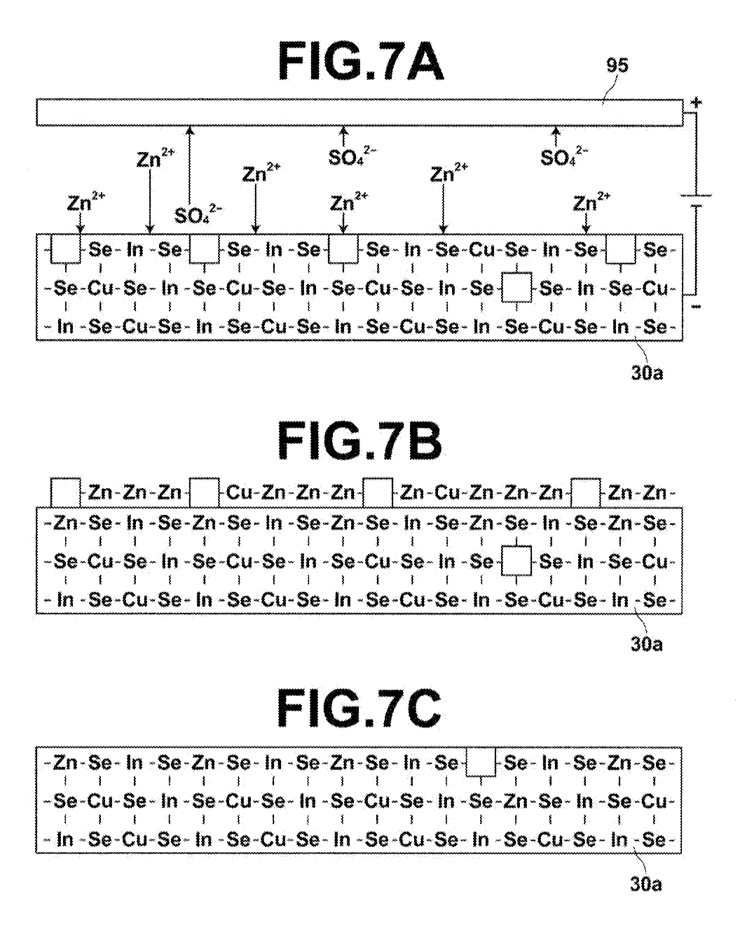

FIGS. 7A through 7C are schematic diagrams illustrating the state of a surface layer in a process of forming a pn junction.

As illustrated in FIG. 7A, Zn²⁺ is attracted to the surface side of the light absorption layer 30 when voltage is applied between the counter electrode 95 and the lower electrode 20. At this time, many vacancies 31 are present in the surface layer 30a.

As illustrated in FIG. 7B, Zn²⁺ attracted to the surface layer 30a diffuses in the light absorption layer 30 by entering vacancies 31 in the surface layer or by substituting Cu in the surface layer 30a. Accordingly, a pn junction is formed. Zn²⁺ that has not diffused in the light absorption layer 30 is deposited on the surface layer 30a. Voltage should be applied for about a few seconds to more than ten seconds.

After then, a Zn coating deposited on the surface is removed by a weak acid solution (for example, hydrochloric acid of a concentration of 1 mol/L). As a result, the light absorption layer 30 in which Zn is diffused in the surface layer 30a, as illustrated in FIG. 7C, is obtainable.

As described above, if a method for diffusing multivalent cations in the light absorption layer 30 by electrodeposition is used, it is possible to form a pn junction in an extremely short time period.

Here, when Cd²⁺ is diffused in the light absorption layer, as multivalent cations, if an electrolyte solution of cadmium sulfide is used as a reaction solution, a pn junction can be formed through a process similar to the aforementioned process.

After a pn junction is formed as described above, a window layer 50 and a transparent electrode 60 are deposited on the light absorption layer 30. Further, an extraction electrode 70 is formed. Accordingly, it is possible to produce the photoelectric conversion device 1, as illustrated in FIG. 1.

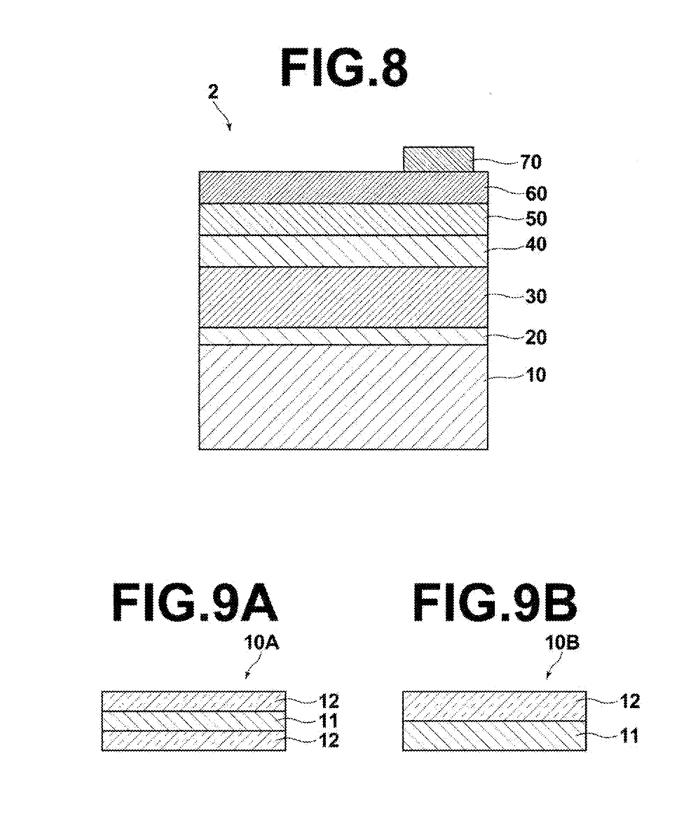

Here, as in a design modification example of the photoelectric conversion device illustrated in FIG. 8, a buffer layer 40 may be formed by a CBD method or the like after a process of forming a pn junction. After then, a window layer 50 may be deposited, and a photoelectric conversion device 2 including the buffer layer 40 may be obtained. For example, the buffer layer 40 is a layer containing at least one of CdS, ZnS, Zn (S, O) and Zn (S, O, OH), as a main component. The thickness of the buffer layer 40 is not particularly limited, but it is desirable that the thickness is in the range of 10 to 500 nm. It is more desirable that the thickness is in the range of 15 to 200 nm.

Alternatively, the buffer layer 40 may be formed after the process of forming vacancies without forming a pn junction by the aforementioned electrodeposition. A pn junction may be formed in the process of forming the buffer layer by diffusing cations of a composition element of the buffer layer in the light absorption layer 30. When the buffer layer is CdS, Cd²⁺ diffuses in the light absorption layer 30, and when the buffer layer is ZnS, Zn(S, O) or Zn(S, O, OH), Zn²⁺ diffuses in the light absorption layer 30, and a pn junction is formed.

For example, when a buffer layer is formed by using a CBD method, the productivity is not sufficient because it needs about a few minutes to tens of minutes. However, if Cu vacancies are formed in the surface layer of the light absorption layer before formation of the buffer layer, as in the present invention, even when the buffer layer is formed by using the CBD method, it is possible to diffuse Zn²⁺ or Cd²⁺ in the light absorption layer in an excellent manner. It is possible to form pn junctions evenly, compared with a case in which a vacancy process is not performed. Further, it is possible to increase the density of diffusion, and to improve the photoelectric conversion efficiency.

When a flexible substrate is used as the substrate, it is desirable to use a so-called roll-to-roll (Roll to Roll) method in the Cu vacancy formation process and/or the pn junction formation process. The roll-to-roll method uses a supply roll (unwinding roll), in which a long flexible substrate is wound in roll form, and a winding roll for winding a substrate after deposition.

Next, each layer of the photoelectric conversion device 1 produced by using the production method of the present invention will be described in detail.

### (Substrate)

FIGS. 9A and 9B are schematic cross sections of substrates 10A and 10B, which are specific modes of the substrate 10. The substrates 10A and 10B are obtained by anodizing at least one of surfaces of a base material 11. It is desirable that the base material 11 is an Al base material containing Al as a main component, a composite base material composed of an Fe material (for example, SUS) containing Fe as a main component and an Al material containing Al as a main component at least on one surface side of the Fe material, or a base material in which an AI coating containing Al as a main component is formed at least on one surface side of a Fe material containing Fe as a main component.

In the substrate 10A illustrated in FIG. 9A, anodized films 12 are formed on both sides of the base material 11. In the substrate 10B illustrated in FIG. 9B, an anodized film 12 is formed on one side of the babe material 11. The anodized films 12 contain Al₂O₃, as a main component. It is desirable that the anodized films 12 are formed on both sides of the substrate 11, as illustrated in FIG. 9A, to suppress a warp of the substrate caused by a difference in thermal expansion coefficients of Al and Al₂O₃, peeling of the film caused by the warp, and the like in a device production process.

Anodization may be performed by using a known method, in which a base material 11 on which a washing process, a polishing and smoothing process, or the like has been performed, if necessary, is used as an anode, and the anode is immersed in an electrolyte together with a cathode. Further, voltage is applied between the anode and the cathode.

The thickness of the base material 11 and the thickness of the anodized film 12 are not particularly limited. When the mechanical strength of the substrate 10, and reduction in the thickness and the weight of the substrate 10 are considered, it is desirable that the thickness of the base material 11 before anodization is, for example, in the range of 0.05 to 0.6 mm. It is more desirable that the thickness is 0.1 to 0.3 mm. When the insulation characteristic of the substrate, the mechanical strength of the substrate, and reduction in the thickness and the weight of the substrate are considered, it is desirable that the thickness of the anodized film 12 is, for example, in the range of 0.1 to 100 μm.

Further, the substrate 10 may include a soda-lime glass (SLG) layer provided on the anodized film 12. When the soda-lime glass layer is provided, it is possible to diffuse Na in the light absorption layer. When the light absorption layer contains Na, the photoelectric conversion efficiency becomes even higher.

### (Lower Electrode)

The main component of the lower electrode (back-side electrode) 20 is not particularly limited. Mo, Cr, W and a combination of these elements are desirable as the main component of the lower electrode 20. Mo, or the like is particularly desirable. The thickness of the lower electrode (back-side electrode) 20 is not limited. It is desirable that the thickness is in the range of about 200 to 1000 nm.

### (Light Absorption Layer)

As described already, the light absorption layer 30 is composed of a composition semiconductor containing Cu_{1-z}In₁₋ₓGaₓSe_{2-y}S_{y} (in the formula, 0≦x≦1, 0≦y≦2, and 0≦z≦1) (CIGS), as a main component.

The thickness of the light absorption layer 30 is not particularly limited. It is desirable that the thickness is in the range of 1.0 to 3.0 μm. It is particularly desirable that the thickness is in the range of 1.5 to 2.0 μm.

### (Window Layer)

The window layer 50 is a middle layer that allows light to enter. The composition of the window layer 50 is not particularly limited. It is desirable that the composition of the window layer 50 is i-ZnO, or the like. The thickness of the window layer 50 is not particularly limited. It is desirable that the thickness is in the range of 10 nm to 200 nm.

### (Transparent Electrode)

The transparent electrode 60 is a layer that allows light to enter. The transparent electrode 60 is paired with the lower electrode 20, and functions as an electrode through which an electric current generated in the light absorption layer 30 flows. The composition of the transparent electrode 60 is not particularly limited, and n-ZnO, such as ZnO: Al, is desirable. The thickness of the transparent electrode 60 is not particularly limited. It is desirable that the thickness is in the range of 50 nm to 2 μm.

### (Extraction Electrode)

The extraction electrode 70 is an electrode for efficiently extracting electric power generated between the lower electrode 20 and the transparent electrode 60 to the outside.

The main component of the extraction electrode 70 is not particularly limited. The main component of the extraction electrode 70 may be Al, or the like. The thickness of the extraction electrode 70 is not particularly limited. It is desirable that the thickness is in the range of 0.1 to 3 μm.

A cover glass, a protection film or the like may be attached to the photoelectric conversion device 1, if necessary, to obtain a solar cell.

It is possible to produce an integrated solar cell by integrating many photoelectric conversion devices 1, illustrated in FIG. 1. When the photoelectric conversion devices 1 are integrated, an extraction electrode for each cell (photoelectric conversion device) is not needed. The integrated solar cell is formed, for example, through a step of forming each layer on a substrate by using a roll-to-roll method using a long flexible substrate, a step of forming a photoelectric conversion device including a patterning (scribe) process for integration, a step of cutting, into a module, the substrate that has formed the device, and the like.

The photoelectric conversion device produced by using the production method of the present invention may be applied not only to solar cells but other purposes, such as a CCD.

### EXAMPLES

Devices having layer structure similar to that of the photoelectric conversion device illustrated in FIG. 1 were produced by using the following methods of examples and comparative examples, and the photoelectric conversion rates of the devices were evaluated.

First, the compositions of layered members used in examples and comparative examples will be described.

### (Layered Member A)

A soda-lime glass (SLG) substrate having a thickness of 1 μm was used as a substrate. A Mo lower electrode having a thickness of 0.8 μm was deposited on the SLG substrate by sputtering. Further, a Cu(In_{0.7}Ga_{0.3})Se₂ layer having a thickness of 1.8 μm was deposited, as a light absorption layer, on the Mo lower electrode by using a three stage method, which is a known method for depositing a CIGS layer, to obtain layered member A.

### (Layered Member B)

An anodized substrate in which an aluminum anodized film (AAO) was formed on an Al surface of a composite base material composed of stainless steel (SUS) and Al was used. Further, a soda-line glass (SLG) layer was formed on the surface of the AAO, and used as the substrate. The thickness of each layer in the substrate was SUS: more than 300 μm, Al: 300 μm, AAO: 20 μm, and SLG: 0.2 μm.

A Mo lower electrode having a thickness of 0.8 μm was deposited on the SLG layer by sputtering. Further, a Cu (In_{0.7}Ga_{0.3})Se₂ layer having a thickness of 1.8 μm was deposited, as a light absorption layer, on the Mo lower electrode by using a three stage method, which is a known method for depositing a CIGS layer, to obtain layered member B.

Next, a Cu vacancy formation process and a pn junction formation process in each of the examples and comparative examples will be described.

In Examples 1-1 through 1-6 and Comparative Example 1-1, Zn²⁺ was used as diffusion ions (cations). In Comparative Example 1-2, Ag¹⁺ was used as diffusion ions (cations).

### Example 1-1

The layered member A was used.

### Cu Vacancy Formation Process:

Tetraethylenepentamine (TEPA) was used as an amine species. A hydrogen peroxide solution of 1.35 weight % was mixed in an aqueous solution of TEPA of about 4.5 weight %. The layered member was immersed in the mixture for two minutes.

### Pn Junction Formation Process:

The layered member after the vacancy formation process was immersed in an aqueous solution of zinc sulfate (pH 3.5). Further, voltage of 1.5 V was applied between a lower electrode and a counter electrode in such a manner that the electric potential on the lower electrode side was lower (the electric potential of the lower electrode was −1.5 V, and the electric potential of the counter electrode was 0 V). Accordingly, Zn²⁺, as multivalent cations, was diffused. The voltage was applied for five seconds.

### Example 1-2

The layered member A was used.

### Cu Vacancy Formation Process:

Ethylenediamine was used as an amine species. A hydrogen peroxide solution of 1.35 weight % was mixed in an aqueous solution of ethylenediamine of about 3.2 weight %. The layered member was immersed in the mixture for two minutes.

### Pn Junction Formation Process:

The process was performed under the same condition as Example 1-1.

### Example 1-3

The layered member A was used.

### Cu Vacancy Formation Process:

Triethylenetetramine was used as an amine species. A hydrogen peroxide solution of 1.35 weight % was mixed in an aqueous solution of triethylenetetramine of about 3.6 weight %. The layered member was immersed in the mixture for two minutes.

### Pn Junction Formation Process:

The process was performed under the same condition as Example 1-1.

### Example 1-4

The layered member A was used.

### Cu Vacancy Formation Process:

The process was performed under the same condition as Example 1-1.

### Pn Junction Formation Process:

The process was performed under a similar condition to Example 1-1 except that the pH of the aqueous solution of zinc sulfate was 6.5.

### Example 1-5

The layered member B was used.

The other conditions were the same as Example 1-1.

### Example 1-6

The layered member A was used.

### Cu Vacancy Formation Process:

The process was performed under the same condition as Example 1-1.

### Pn Junction Formation Process:

The process was performed under a similar condition to Example 1-1 except that the pH of the aqueous solution of zinc sulfate was 8.0.

### Comparative Example 1-1

The layered member A was used.

### Cu Vacancy Formation Process:

This process was not performed.

### Pn Junction Formation Process:

The process was performed under the same condition as Example 1-1.

### Comparative Example 1-2

The layered member A was used.

### Cu Vacancy Formation Process:

The process was performed under the same condition as Example 1-1.

### Pn Junction Formation Process:

The process was performed under a similar condition to Example 1-1 except that Ag⁺ was diffused by using an aqueous solution of silver sulfate.

In Examples 2-1 through 2-6 and Comparative Example 2, Cd²⁺ was used as diffusion ions (cations).

### Example 2-1

The layered member A was used.

### Cu Vacancy Formation Process:

Tetraethylenepentamine (TEPA) was used as an amine species. A hydrogen peroxide solution of 1.35 weight % was mixed in an aqueous solution of TEPA of about 4.5 weight %. The layered member was immersed in the mixture for two minutes.

### Pn Junction Formation Process:

The layered member after the vacancy formation process was immersed in an aqueous solution of cadmium sulfate (pH 3.5). Further, voltage of 1.7 was applied between a lower electrode and a counter electrode in such a manner that the electric potential on the lower electrode side was lower (the electric potential of the lower electrode was −1.7 V, and the electric potential of the counter electrode was 0 V). Accordingly, Cd²⁺, as multivalent cations, diffused. The voltage was applied for seven seconds.

### Example 2-2

The layered member A was used.

### Cu Vacancy Formation Process:

Ethylenediamine was used as an amine species. A hydrogen peroxide solution of 1.35 weight % was mixed in an aqueous solution of ethylenediamine of about 3.2 weight %. The layered member was immersed in the mixture for two minutes.

### Pn Junction Formation Process:

The process was performed under the same condition as Example 2-1.

### Example 2-3

The layered member A was used.

### Cu Vacancy Formation Process:

Triethylenetetramine was used as an amine species. A hydrogen peroxide solution of 1.35 weight % was mixed in an aqueous solution of triethylenetetramine of about 3.6 weight %. The layered member was immersed in the mixture for two minutes.

### Pn Junction Formation Process:

The process was performed under the same condition as Example 2-1.

### Example 2-4

The layered member A was used.

### Cu Vacancy Formation Process:

The process was performed under the same condition as Example 2-1.

### Pn Junction Formation Process:

The process was performed under a similar condition to Example 2-1 except that the pH of the aqueous solution of cadmium sulfate was 6.0.

### Example 2-5

The layered member B was used.

### Cu Vacancy Formation Process:

The process was performed under the same as Example 2-1.

### Pn Junction Formation Process:

The process was performed under the same as Example 2-4.

### Example 2-6

The layered member A was used.

### Cu Vacancy Formation Process:

The process was performed under the same condition as Example 2-1.

### Pn Junction Formation Process:

The process was performed under a similar condition to Example 2-1 except that the pH of the aqueous solution of cadmium sulfate was 9.0.

### Comparative Example 2

The layered member A was used.

### Cu Vacancy Formation Process:

This process was not performed.

### Pn Junction Formation Process:

The process was performed under the same condition as Example 2-1.

In Example 3 and Comparative Example 3, Cd²⁺ was used as diffusion ions (cations). As a method for forming a pn junction, a buffer was formed by using a CBD method instead of the aforementioned electrodeposition.

### Example 3

The layered member A was used.

### Cu Vacancy Formation Process:

Tetraethylenepentamine (TEPA) was used as an amine species. A hydrogen peroxide solution of 1.35 weight % was mixed in an aqueous solution of TEPA of about 4.5 weight %. The layered member was immersed in the mixture for two minutes.

Pn Junction Formation Process:

A reaction solution was prepared by mixing a predetermined amount of aqueous solution of cadmium sulfate, a predetermined amount of aqueous solution of thiourea, and a predetermined amount of aqueous solution of ammonia together so that cadmium sulfate: 0.015 M, and thiourea: 1.5 M, and ammonia: 1.9M. Here, the unit M represents volume molar concentration (mol/L). While the aforementioned prepared solution was kept at 80° C., the layered member A that has been processed with tetraethylenepentamine was immersed in the solution for ten minutes. Accordingly, CdS was deposited, as a buffer layer.

### Comparative Example 3

The layered member A was used.

### Cu Vacancy Formation Process:

This process was not performed.

### Pn Junction Formation Process:

The process was performed under the same condition as Example 3.

### <Production of Solar Cell>

With respect to a layered member on which a pn junction formation process has been performed by using a method of each of examples and comparative examples, an i-ZnO layer (window layer) and an n-ZnO layer (transparent electrode layer) were sequentially deposited on the light absorption layer. Finally, an extraction electrode (upper electrode) composed of Al was formed. Accordingly, a single-cell solar cell was produced. The thickness of each layer was i-ZnO layer: 50 nm, n-ZnO layer: 300 nm, and Al: 1 μm.

### <Method for Measuring Photoelectric Conversion Efficiency>

With respect to each solar cell produced by a method of each of the examples and the comparative examples, a photoelectric conversion efficiency was measured by using a solar simulator under a condition using pseudo solar light of Air Mass (AM)=1.5 and 100 mW/cm².

Table 1 shows obtained photoelectric conversion efficiencies together with the conditions of a vacancy process and a pn junction in Examples 1-1 through 1-6 and Comparative Examples 1-1 and 1-2. Table 2 shows obtained conversion efficiencies together with the conditions of a vacancy process and a pn junction in Examples 2-1 through 2-6 and Comparative Example 2. Further, Table 3 shows obtained photoelectric conversion efficiencies together with the conditions of a vacancy process and a pn junction in Example 3 and Comparative Example 3.

In each of the tables, the photoelectric conversion efficiencies are represented based on a photoelectric conversion rate about a device produced by performing a pn junction process without performing a vacancy formation process. The photoelectric conversion efficiencies are represented as values against a reference value. When cation species are different from each other, the conversion efficiency differs. Therefore, with respect to Examples 1-1 through 1-6 and Comparative Example 1-2 in Table 1, the conversion efficiency of Comparative Example 1-1 was used as a reference. With respect to Examples 2-1 through 2-6 in Table 2, the conversion efficiency of Comparative Example 2 was used as a reference. In Table 3, with respect to Example 3 in which a pn junction process was performed not in electrodeposition but during formation a buffer by using a CBD method, the conversion efficiency of Comparative Example 3, in which a similar pn junction process was performed, was used as a reference.

TABLE 1

| | | | | | | | | Comparative | Comparative |
|---|---|---|---|---|---|---|---|---|---|
| | | Example | Example | Example | Example | Example | Example | Example | Example |
| | | 1-1 | 1-2 | 1-3 | 1-4 | 1-5 | 1-6 | 1-1 | 1-2 |
| Vacancy | Amine | Tetra- | Ethylene- | Triethylene- | Tetra- | Tetra- | Tetra- | None | Tetra- |
| Formation | Species | ethylene- | diamine | tetramine | ethylene- | ethylene- | ethylene- | | ethylene- |
| Process | | pentamine | | | pentamine | pentamine | pentamine | | pentamine |
| pn | Cation | Zn²⁺ | Zn²⁺ | Zn²⁺ | Zn²⁺ | Zn²⁺ | Zn²⁺ | Zn²⁺ | Ag¹⁺ |
| Junction | pH during | 3.5 | 3.5 | 3.5 | 6.5 | 3.5 | 8.0 | 3.5 | 3.5 |
| Formation | Electro- | | | | | | | | |
| Process | deposition | | | | | | | | |

| | | | | | | | | |
|---|---|---|---|---|---|---|---|---|
| Conversion Efficiency | +3.6% | +2.8% | +3.1% | +3.4% | +3.4% | −0.5% | Reference | Not |
| (against Reference) | | | | | | | | Measurable |

TABLE 2

| | | Example | Example | Example | Example | Example | Example | Comparative |
|---|---|---|---|---|---|---|---|---|
| | | 2-1 | 2-2 | 2-3 | 2-4 | 2-5 | 2-6 | Example 2 |
| Vacancy | Amine | Tetra- | Ethylene- | Triethylen- | Tetra- | Tetra- | Tetra- | None |
| Formation | Species | ethylene- | ediamine | tetetramine | ethylene- | ethylene- | ethylene- | |
| Process | | pentamine | | | pentamine | pentamine | pentamine | |
| pn | Cation | Cd²⁺ | Cd²⁺ | Cd²⁺ | Cd²⁺ | Cd²⁺ | Cd²⁺ | Cd²⁺ |
| Junction | pH during | 3.5 | 3.5 | 3.5 | 6.0 | 6.0 | 9.0 | 6.0 |
| Formation | Electro- | | | | | | | |
| Process | deposition | | | | | | | |

| | | | | | | | |
|---|---|---|---|---|---|---|---|
| Conversion Efficiency | +1.6% | +0.8% | +1.3% | +1.4% | +1.5% | −0.4% | Reference |
| (against Reference) | | | | | | | |

TABLE 3

| | | Example 3 | Comparative Example 3 |
|---|---|---|---|
| Vacancy | Amine | tetraethylenepentamine | None |
| Formation | Species | | |
| Process | | | |
| pn | Cation | Cd²⁺ | Cd²⁺ |
| Junction | CBD | CdS Buffer Layer | CdS Buffer Layer |
| Formation | Method | Formation | Formation |
| Process | | | |

| | | |
|---|---|---|
| Conversion Efficiency | +1.4% | Reference |
| (against Reference) | | |

As Table 1 shows, conversion efficiencies of Examples 1-1 through 1-5 were higher than Comparative Example 1-1, in which no vacancy formation process was performed, by 2.8% or more.

Especially, when a vacancy process was performed using triethylenetetramine or tetraethylenepentamine, the conversion efficiencies improved greatly by 3.1% or more, compared with Comparative Example 1-1.

Meanwhile, although a vacancy process similar to Example 1-1 was performed in Example 1-6, conversion efficiency of Example 1-6 was lower than or equal to a reference value. Since a vacancy process similar to Example 1-1 was performed, it is considered that vacancies were formed in an excellent manner. However, it is considered that Zn²⁺ did not diffuse in the light absorption layer sufficiently, because pH of the reaction solution during electrodeposition was 8.0, which is alkaline, and the reaction solution became milky, and ZnOH, which is a hydroxide, was deposited, and that the insufficient diffusion of Zn²⁺ cancelled the effect of the vacancy formation process, and the conversion efficiency became substantially similar to the reference. Nevertheless, it is estimated that a high photoelectric conversion efficiency was achieved, compared with a case in which the reaction solution of the same condition is used in electrodeposition and no vacancy formation process is performed.

As in Comparative Example 1-2, when Ag⁺, which is a monovalent cation, was diffused instead of multivalent cations in an electrodeposition step, the conversion efficiency was too low to be measured. It is considered that the conversion efficiency was low because monovalent cations could not form a pn junction, and a photoelectric conversion function was not provided.

As Table 2 shows, in Examples 2-1 through 2-5, in which Cd ions diffused in the light absorption layer, the conversion efficiency was higher than Comparative Example 2, in which no vacancy formation was performed, by 0.8% or more.

Especially, when a vacancy process was performed by using triethylenetetramine or tetraethylenepentamine, the conversion efficiency was higher than Comparative Example 2 by 1.3% or more.

Meanwhile, in Example 2-6, a vacancy process similar to Example 2-1 was performed, but the conversion efficiency was lower than or equal to a reference value. Since a vacancy process similar to Example 2-1 was performed, it is considered that vacancies were formed in an excellent manner. However, it is considered that Cd²⁺ did not diffuse in the light absorption layer sufficiently, because pH of the reaction solution during electrodeposition was 9.0, which is alkaline, and the reaction solution became milky, and CdOH, which is a hydroxide, was deposited, and that the insufficient diffusion of Cd⁺ cancelled the effect of the vacancy formation process, and the conversion efficiency was substantially similar to the reference. Nevertheless, it is estimated that a high photoelectric conversion efficiency was achieved, compared with a case in which the reaction solution of the same condition is used in electrodeposition and no vacancy formation process is performed.

Further, as shown in Table 3, even when a method for forming a pn junction does not involve electrodeposition but formation of a buffer by using a CBD method, a high photoelectric conversion efficiency was achieved by performing a vacancy process as in Example 3, compared with Comparative Example 3, in which no vacancy process was performed.

As described above, when a pn junction was formed after a Cu vacancy formation process was performed on a light absorption layer, the photoelectric conversion efficiency improved, compared with a case in which a pn junction was performed under a similar condition but without performing a Cu vacancy formation process. It is clear that an excellent pn junction was formed. Further, it has become clear that when a pn junction is formed by electrodeposition, an excellent pn junction is achievable if the pH of an aqueous solution including multivalent cations is about 0 to 7.

What is claimed is:

1. A method for producing a photoelectric conversion device including a light absorption layer made of a CIGS-based compound semiconductor, wherein a vacancy formation process for forming Cu vacancies in a surface layer of the light absorption layer in a layered member that is composed of a lower electrode and the light absorption layer deposited on a substrate is performed, and after then, a pn junction is formed in the surface layer of the light absorption layer.

2. The method for producing a photoelectric conversion device, as defined in claim 1, wherein the layered member is immersed in a reaction solution containing multivalent cations, and the pH of which is in the range of 0 to 7, and the pn junction is formed by arranging a counter electrode for applying an electric field in such a manner to face the light absorption layer, and by diffusing the multivalent cations from the surface layer of the light absorption layer to the inside of the light absorption layer by inducing a difference in electric potential between the counter electrode and the lower electrode in such a manner that the electric potential of the lower electrode is lower than that of the counter electrode.

3. The method for producing a photoelectric conversion device, as defined in claim 1, wherein at least a surface layer of the layered body is immersed in an aqueous solution containing at least one kind of amines, as the vacancy formation process.

4. The method for producing a photoelectric conversion device, as defined in claim 3, wherein the at least one kind of amines is selected from a group consisting of ethylenediamine, diethylenetriamine, triethylenetetramine, tetraethylenepentamine, and pentaethylenehexamine.

5. The method for producing a photoelectric conversion device, as defined in claim 1, wherein the multivalent cations are ions of a IIa group or IIb group element.

6. The method for producing a photoelectric conversion device, as defined in claim 1, wherein an anodized substrate selected from a group consisting of an anodized substrate in which an anodized film containing Al₂O₃ as a main component is formed at least on one surface side of an Al base material containing Al as a main component, an anodized substrate in which an anodized film containing Al₂O₃ as a main component is formed at least on one surface side of a composite base material composed of an Fe material containing Fe as a main component and an Al material containing Al as a main component at least on one surface side of the Fe material, and an anodized substrate in which an anodized film containing Al₂O₃ as a main component is formed at least on one surface side of a base material in which an Al coating containing Al as a main component is formed at least on one surface side of a Fe material containing Fe as a main component is used, as the substrate.
